(19) United States
(12) Patent Application Publication
(10) Pub. No.: US 2016/0163902 A1
(43) Pub. Date: Jun. 9, 2016

(54) SOLAR MODULE HAVING SHINGLED SOLAR CELLS

(71) Applicant: PI Solar Technology GmbH, Berlin (DE)

(72) Inventor: Lars PODLOWSKI, Berlin (DE)

(21) Appl. No.: 14/943,039

(22) Filed: Nov. 17, 2015

Related U.S. Application Data
(60) Provisional application No. 62/087,814, filed on Dec. 5, 2014.

(51) Int. Cl. H01L 31/05; H02S 20/25

(52) U.S. Cl. CPC H01L 31/0508; H02S 20/25

(57) ABSTRACT

A solar panel includes a plurality of solar cells electrically connected to one another in a string along a string direction. Each of the solar cells are made up of solar cell strips that are shingled with respect to one another along a shingling direction. The shingling direction is perpendicular to the string direction.

### CROSS-REFERENCE TO PRIOR APPLICATION

Priority is claimed to U.S. Provisional Application Ser. No. 62/087,814 filed on Dec. 5, 2014, the entire disclosure of which is hereby incorporated by reference herein.

### FIELD

The present invention relates to a solar panel having shingled solar cells, a method of producing the same and a method for preventing the failure of solar cells due to thermally induced mechanical stress.

### BACKGROUND

A common material used for solar cells is crystalline silicon. The most common design is such that one electrical contact of the solar cell is its front side, and the other electrical contact is on its backside.

Generally, solar modules are designed such that individual solar cells are connected in series and laminated behind a tempered high-transmittance safety glass. One severe long-term reliability issue for such solar panels results from the fact that thermal expansion coefficients of the front glass and the solar cells are very different from each other. This leads to high thermal stresses on the fragile solar cells, which are especially problemsome where the solar cells are connected to each other in 6-12 pieces (as is typically the case) in a row to form a so-called “string”.

In most conventional panel designs, the solar cell interconnectors (which lead from the front side of one cell to the rear side of the next cell) not only electrically connect the solar cells to each other, but also act as a stress relief band. If the cell interconnection material is properly selected and attached, the lifetime of a good solar panel today is >20 years.

This standard interconnection of solar cells requires the solar cells to have a certain spacing between one another because the interconnector has to get from the front side of one cell to the backside of the other cell, typically by a smooth s-form shape. The presence of these gaps reduces the area efficiency of the solar panel. Additionally, the connector on the front side of the solar cells itself causes shading on small portions of the solar panel, thereby reducing the amount of solar cell power which can be produced over the total area of the solar panel.

In order to avoid the decrease in area efficiency caused by the gaps and to provide an easy way to connect the front to the back of adjacent solar cells, a shingling concept was proposed decades ago. This concept avoids additional interconnectors between the cells and also increases the area efficiency of the solar panel because the full area of the solar panel can be covered with the solar-active material.

However, this concept of shingled solar cells has one severe technical issue: there is no stress relief between the solar cells, and the thermal expansion of the cover glass results in high thermal tension within the solar cells or at the areas of their interconnection. What typically can be observed in accelerated stress tests is that the solar cells become fractured, thereby leading to a total failure of the solar module. Because this severe technical issue could not be solved, the shingling concept was abandoned and never became commercially relevant.

### SUMMARY

In an embodiment, the present invention provides a solar panel including a plurality of solar cells electrically connected to one another in a string along a string direction. Each of the solar cells are made up of solar cell strips that are shingled with respect to one another along a shingling direction. The shingling direction is perpendicular to the string direction.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1a shows a conventional solar cell. The most common design uses a 156 mm×156 mm silicon wafer as a base. On the front side there is a grid consisting out of three so-called busbars and a large number of thin grid fingers.

FIG. 1b shows a ⅙ cut of a solar cell which has the dimension of 156 mm×26 mm. The design of the front grid has been modified to fit to the new dimension.

FIG. 2a shows how several solar cell strips are connected to each other by shingling in an embodiment: one solar cell slightly overlaps the next cell along the long edge. To the first and the last cell cables, e.g., flat cables are attached.

FIG. 2b illustrates, in a view onto a front, a rectangular shape of the sub-assembly consisting of several shingled cell strips which can have a size similar to the original cell (depending on the numbers of shingles).

FIG. 3a shows how conventional solar cells (in this case: 4 pcs) are connected to a so-called string by using flat tin-coated copper wires which connect the front side of one cell to the backside of the next cell.

FIG. 3b shows that in an embodiment of the invention a string consists of several sub-assemblies. It is illustrated that the shingling direction within a sub-assembly is perpendicular to the string direction. All sub-assemblies are connected in parallel by two flat coated copper wires.

FIG. 3c shows further embodiment in which every 2^{nd} subassembly is rotated by 180° and all sub-assemblies are connected in series.

FIG. 4a shows the most simple string design consisting just of two sub-assemblies which are connected in parallel.

FIG. 4b illustrates the electrical polarity within such a string out of two sub-assemblies which are connected in parallel.

FIG. 4c shows schematically the current flow within the string design according to an embodiment of the invention.

FIG. 5 illustrates how—instead of a pure straight wire—an additional stress relief is applied in an embodiment of the invention in order to improve flexibility along the string direction.

FIG. 6a shows a string design consisting also out of two sub-assemblies but which are rotated 180° with respect to each other and connected in series.

FIG. 6b illustrates the electrical polarity within such a string design. All shingled cells strips and also all sub-assemblies are connected in series.

FIG. 6c shows schematically a meandering current flow within the string design according to an embodiment of the invention.

FIG. 7a again shows two sub-assemblies connected in series by a straight flat wire.

FIG. 7b shows, for the case of the rotated sub-assemblies between the “+” pole of one sub-assembly and the “−” pole of the next sub-assembly, the attachment of an electronic device for electrically bypassing both sub-assemblies.

FIG. 8a shows how, in case of parallel oriented sub-assemblies, basically a full coverage of the area with solar-active material can be achieved by a shingling of the strings.

FIG. 8b shows a cross section of such a shingling of strings.

### DETAILED DESCRIPTION

One way to increase the area efficiency of the solar module is to shingle the individual solar cells in order to minimize non-active areas of the module. Also electrical losses due to the resistivity of solar cell interconnectors are avoided this way. However, a design for a solar module which uses shingled solar cells must address the thermal stress issue which arises from the fact that the front glass and the silicon solar cells have very different thermal expansion coefficients.

The proposed solution according to an embodiment is to make only small-size sets of shingles (which are small enough to limit thermal stress) and to arrange them in a way that the shingling direction and the direction of the string are perpendicular to each other. This leads to an effective reduction of the thermal stress and at the same time increases the effective active solar area. As a result, the proposed solar panels design leads to a high area efficiency, a long lifetime also under extreme temperature conditions, allows many variations for current/voltage ratios and it can be made to be very forgiving in case of partial shading.

The proposed design also is very beneficial with respect to implement bypass diodes.

One way to increase the area efficiency of the solar module is to shingle solar cells in order to avoid the usage of solar cell interconnectors which lead to shading. Also electrical losses due to the resistivity of solar cell interconnectors are avoided this way. However, a design for a solar module which uses shingled solar cells must address the thermal stress issue. The thermal expansion coefficient of glass and of silicon are very different from each other which leads to significant thermal stress to the solar cells and may result in a very short lifetime of the product.

Just recently, a concept for a module using shingled solar cells for solar concentrator applications has been published [US patent document US 20140124014A1]: only a few numbers of solar cells are shingled to sets of 5 cells (in this case), and in order to overcome the thermal stress in long chains the sets are connected to each other with a stress relief tool. In the respective patent application, various design ideas are shown to overcome the thermal stress. However, all of the designs ideas share one common concept that the shingling of the cell strips and the stress relief is along the direction of the string.

An embodiment of the invention here has a very different approach for resolving the thermal stress problem along the string direction: the shingle direction and the string (and predominant stress) direction are perpendicular to each other. Also the shingled solar cell strips can be arranged in certain sets (“sub-assemblies”) which are small enough that the thermal stress within such a set is limited. Additionally, these sets can be connected to each other perpendicular to the shingling direction.

This approach avoids the usual issue that the interconnection between two sub-assemblies is between both adjacent edges of the sub-assemblies, i.e. in the string direction. Here, this is not the case, but rather the sub-assemblies are connected along the outer edges of a string.

The shown technical solution according to an embodiment not only leads to a very effective thermal stress relief, but at the same time only a very small area of the aperture is covered by any connector material which leads to a very high module area efficiency. If, for the interconnection, a structured ribbon is used, which can reflect the incident light, then area losses can be further reduced.

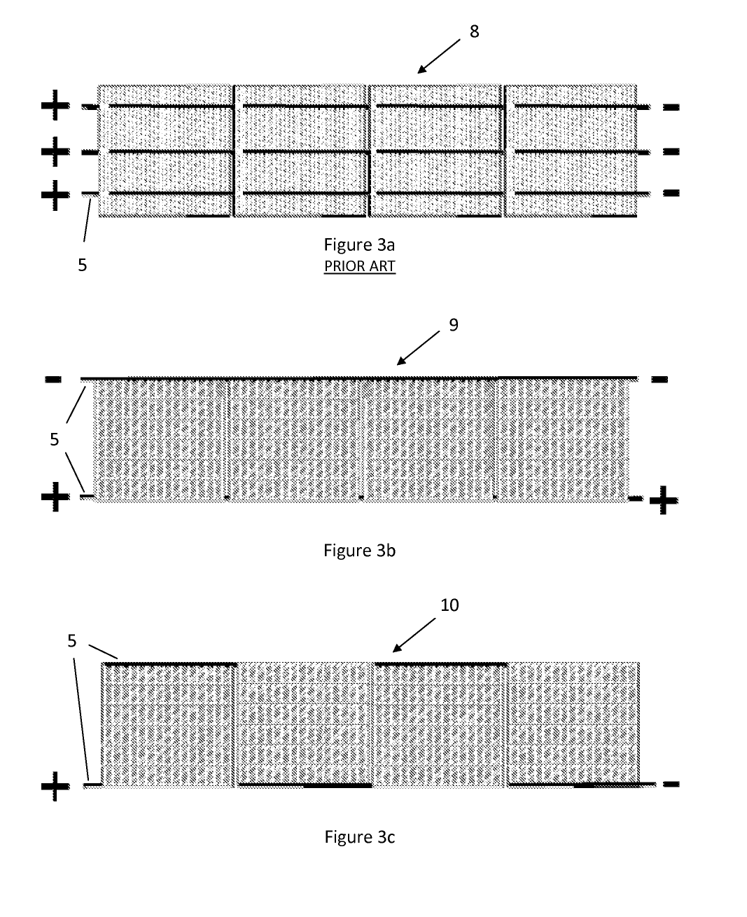

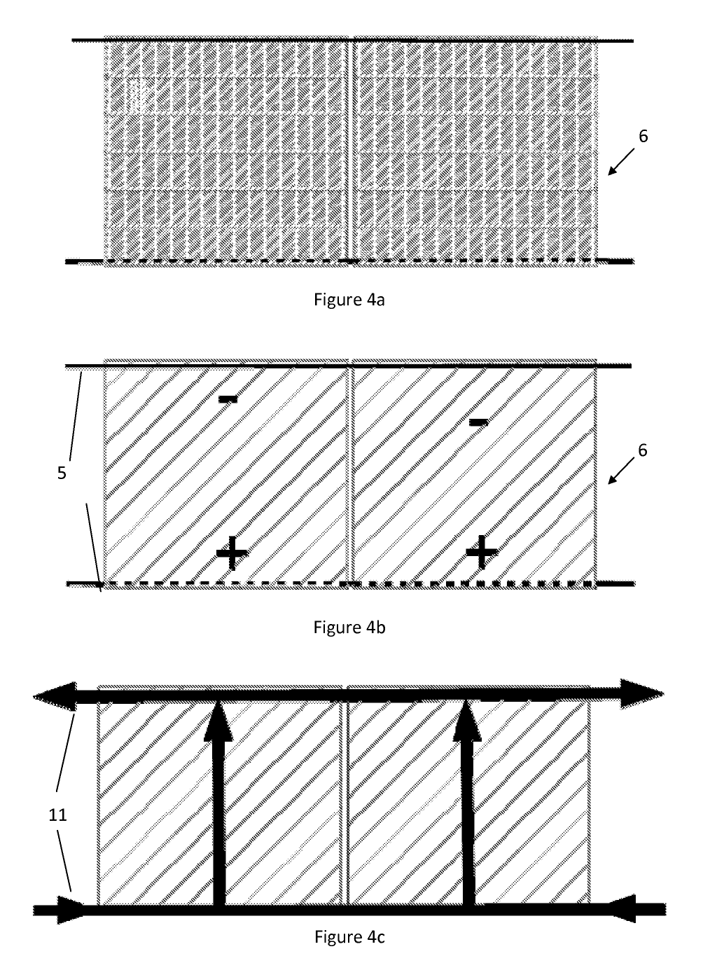

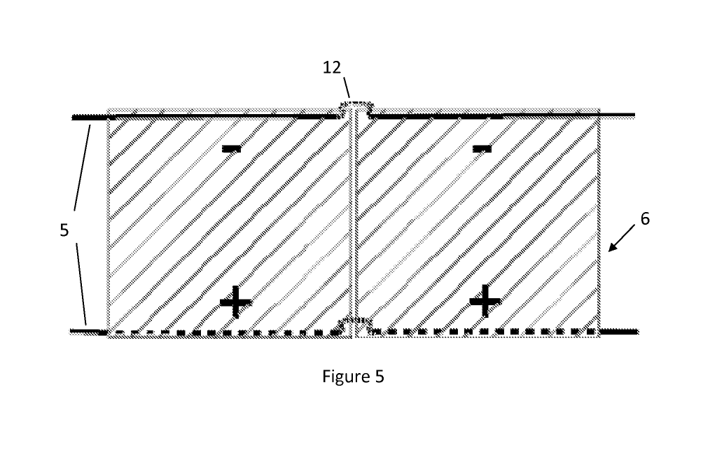

For this general approach of “shingling perpendicular to the string” two different embodiments are provided. In a first embodiment, the orientation of the polarities of all sub-assemblies are the same, and they are all connected in parallel by two long flat wires (FIGS. 3b and 4a), one for each polarity. An additional stress relief can also be applied (FIG. 5). The voltage of the entire string is the same as of one sub-assembly, and the currents of all sub-assemblies add to each other. Therefore, this is a “low voltage—high current” version.

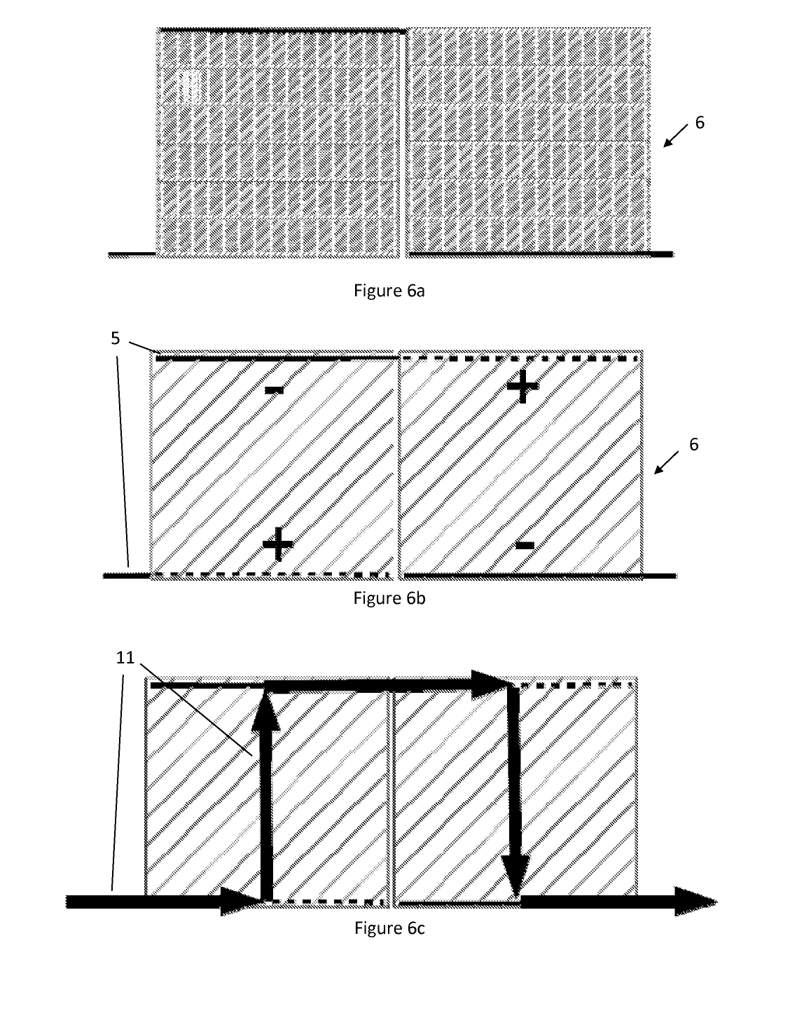

In a second embodiment, two sub-assemblies of shingled cells are oriented 180° rotated to each other (FIGS. 3c and 6a). The opposite orientation leads to the fact that always one pole of one set is connected to the other pole of the other sub-assembly (see FIG. 6b), which leads to a series connection. The interconnection can also be done by a flat wire, e.g., similar material to what is used for the interconnection of conventional solar cells, but it connects only two sub-assemblies, respectively.

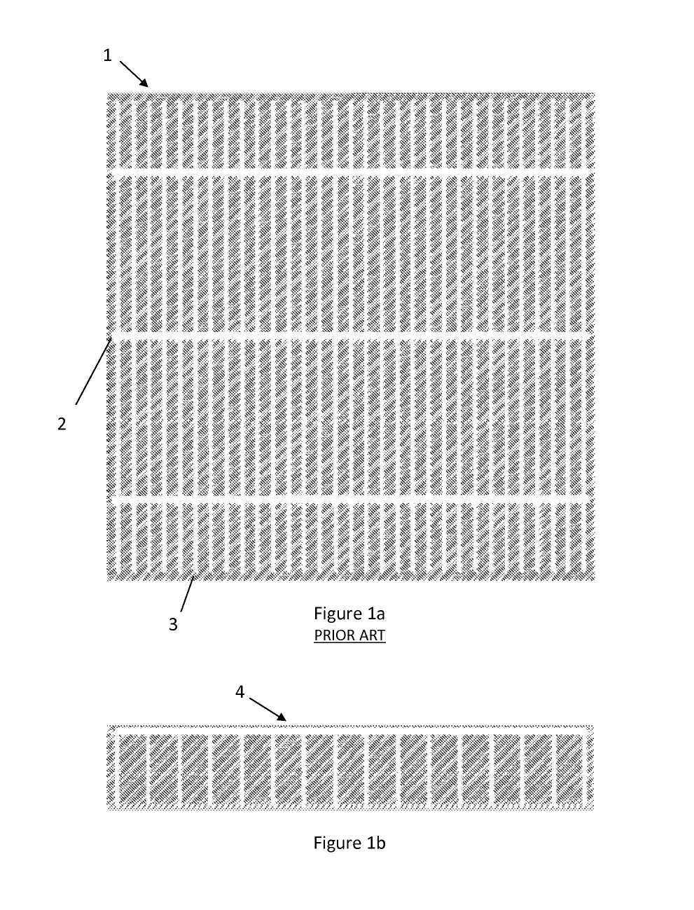

FIG. 1a shows a conventional solar cell 1. The most common design uses a 156 mm×156 mm silicon wafer as a base. On the front side there is an electrically conductive grid consisting out of three (typically) so-called busbars 2 and a large number of thin grid fingers 3. The grid collects the generated charge carriers out of the wafer, and can be made by screen printing a silver-based paste onto the wafer (although also other techniques, e.g. electro-plating can also be used).

In an embodiment of the invention shown in FIG. 1b, a solar cell is cut into or produced in smaller strips 4 of identical size, e.g. 6 strips of 156 mm×26 mm. Other strip widths are also possible, e.g., into only 4 strips (of 39 mm width) or even 8-10 strips with a respectively smaller width. The screen print is modified accordingly, and important in this embodiment is that per cell strip one busbar along the long side is provided (see FIG. 1b). It should be as close to the edge as technically possible.

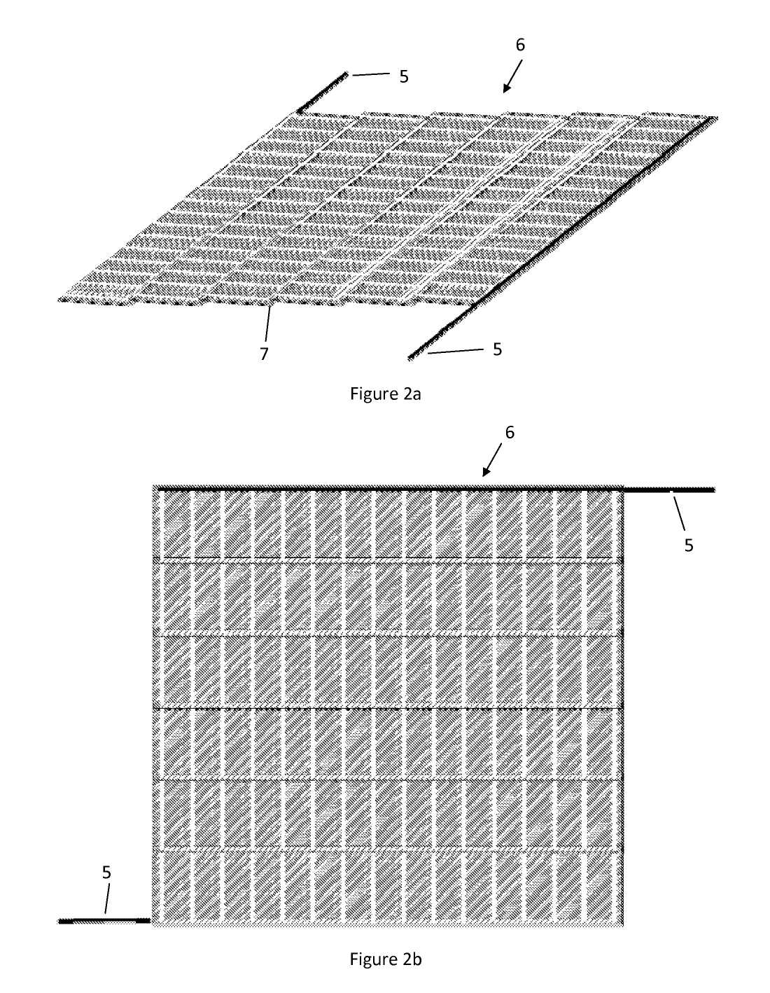

Several solar cell strips 4 are connected to each other by shingling: one solar cell strip 4 has a slight overlap 7 to the next cell strip 4 along the long edge (see FIG. 2a), and the front side of one cell strip 4 is both electrically and mechanically connected to the back side of the next cell strip 4, e.g. by using a conductive adhesive. The smaller the overlap 7 the more effectively the solar active material will be used, but, on the other hand, of course a good electrical connection should be established which requires a certain minimum overlapping area.

When viewed onto the front (FIG. 2b) of such a shingled sub-assembly 6, the rectangular shape of the sub-assembly 6 can be seen and consists of several shingled cell strips 4. Such a sub-assembly can have a size similar to the original cell but can also be smaller or larger (depending on the numbers and size of shingles). This example of a sub-assembly 6 (using six ⅙ strips 4) is slightly smaller than the original cell 1 because some area is lost due to the five overlaps.

In a solar panel a lot of solar cells need to get connected. In a first step several cells get connected in one direction to a so-called string. Then several strings are placed side-by-side and electrically connected and finally laminated behind a sheet of tempered front glass.

For conventional solar cells 1 the most common technology to form a string 8 is to use flat tin-coated copper wires 5 (“ribbon”) which connects the front side of one cell 1 to the backside of the next cell 1. In FIG. 3a, a string made out of four solar cells 1 is shown by way of example, but the industry standard currently is to have 8-12 cells per string 8 which leads to a string length in the range of 1.4-2.0 meters. Over such long distances, a string 8 will face a lot of stress because the thermal expansion of the glass is much higher than that of the silicon solar cell (3.5×). In the conventional solar cell string 8, the interconnecting ribbons 5 act as a stress relief.

In an embodiment of the invention, a string is built in a different manner. It includes several solar cells that are sub-assemblies of strips. While a string having sub-assembles has already been described before [e.g. US patent document US 20140124014A1], the previous designs exclusively provide the shingling direction along the string direction, leading to significant thermal stress along the shingling direction. In the previous designs, in order to ensure a long-term stability, sophisticated stress relief methods had to be developed, leading either to area losses or higher costs or both.

In contrast, in this invention, according to an embodiment, the shingling direction within a sub-assembly is perpendicular to the string direction. This is the key element in an embodiment.

As seen in FIG. 3b-c, the interconnection between two sub-assemblies is not between both adjacent edges, but rather along the outer edges of a string 9, 10. In a simple form, the interconnection can also be done by a conventional flat metal wire (ribbon) 5. Such a metal wire is fairly soft and effectively acts as a stress relief. Providing the shingling direction perpendicular to the string direction advantageously leads to only very limited thermal stress to the solar cell shingles and its interconnection contacts. The FIGS. 3b and 3c show two versions of how such a string 9, 10 can be arranged, and both versions will now be described in more detail using FIGS. 4 and 5, respectively. FIG. 3b shows a first string 9 out of four parallel oriented sub-assemblies 6 and FIG. 3c shows a second string 10 out of four sub-assemblies 6 with neighbors are rotated 180° to each other.

FIGS. 4a-c illustrate a parallel orientation of sub-assemblies 6 with the most simple string design which consists of just two sub-assemblies. In the FIGS. 4b-c, one sub-assembly 6 is shown in a simplified manner as just one unit without the individual shingles. A dashed line indicates that here a flat wire 5 runs along the backside of the sub-assembly. FIG. 4b illustrates the electrical polarization within a string 9 consisting out of two sub-assemblies 6 which have the same orientation. Both sub-assemblies 6 are connected in parallel by two straight flat wires 5 which run along the outer edge of the string 9 on the front side and on the back side, respectively.

FIG. 4c shows very schematically the current flow 11 within this embodiment.

Although a metal wire 5 conceptually acts as a stress relief, FIG. 5 illustrates how—instead of a straight wire—an additional stress relief 12, e.g., a flexible, looped metal wire, can be applied in order to further improve flexibility along the string direction. This can be an advantage in case of exposure of the panel to an extra-ordinary large temperature range the panel.

FIGS. 6a-c show the other string 10 where every sub-assembly 6 is rotated 180° to its neighbor.

FIG. 6b illustrates the electrical polarity within such a string 10. Not only are all shingled cell strips 4 connected to each other in series, but also all sub-assemblies 6 are connected in series.

FIG. 6c shows very schematically the current flow within the string 10. In contrast to a conventional string 8 and shingle concepts like US 20140124014A1 where the current direction is straight with the string orientation, in this embodiment of the present invention, the current direction in the string 10 meanders.

Of course, any kind of mixed arrangement of both versions (parallel or 180°-rotated orientation of sub-assemblies) is also possible, e.g. always two sub-assemblies that are oriented in parallel, but then are connected in series to the next two sub-assemblies. So different embodiments of sub-assemblies shingled perpendicular to the string direction provides great flexibility for current/voltage combinations for a solar panel.

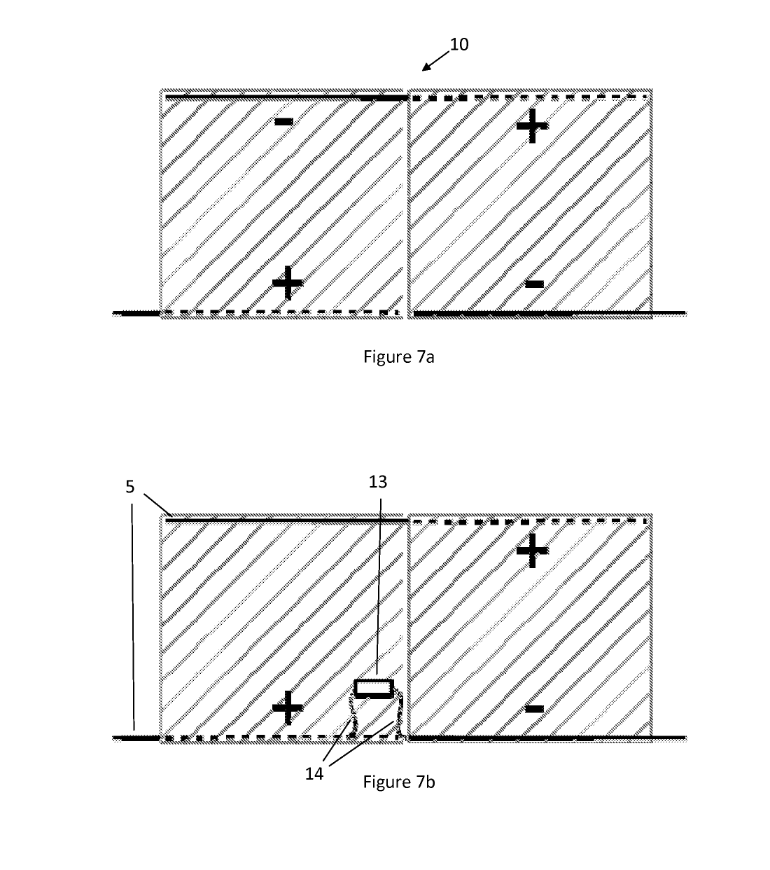

Also, it has been discovered that the “high voltage—low current” embodiment with a series connection of the sub-assemblies (FIGS. 6a-c) can provide additional features and advantages. FIG. 7a again shows the base design of string 10 with both sub-assemblies 6 rotated 180° to each other and connected in series by a straight flat wire 5.

The “high voltage—low current” embodiment shown in FIGS. 6a-c and 7a-b can also be used for a special application as very shade-tolerant solar panels, as this design is very beneficial with respect to implementing many electrical bypasses. Those bypasses are usually done by diodes, but also active micro-electronic switches are available. A certain amount of bypass elements 13 are usually required for solar panels in order to protect the solar cells in case of partial shading, but having many bypasses would require a lot of sophisticated additional wiring, which is too expensive. As seen in FIG. 7b, in case of the rotated sub-assemblies the “+” pole of one sub-assembly and the “−” pole of the next sub-assembly are right next to each other and therefore an electronic device for electrically bypassing both sub-assemblies 6, or a bypass element 13 can be attached very easily without any sophisticated additional wiring, for example, using an electrical connector 14 from the flat wire 5 to the bypass element 13.

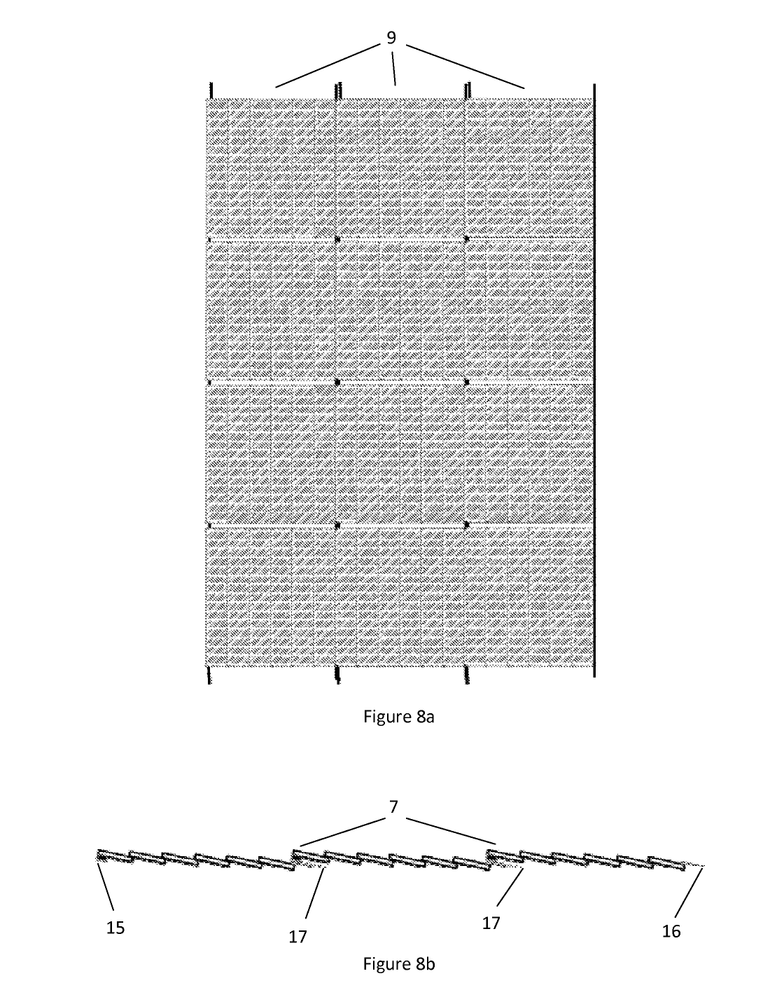

The “low voltage—high current” embodiment where all sub-assemblies are oriented in parallel can be applied to a very beneficial module design option: since all visible interconnectors (which lead to area efficiency losses) are on one side of the string 9 (see FIGS. 3b and 4b), one next string 9 can be placed that covers the connector area of the adjacent string 9, i.e. basically a shingling of full strings 9 (see FIG. 8a). In the displayed example, there are three strings 9 of four cells each which are arranged to achieve highest area efficiency.

FIG. 8b shows the cross section of three overlapping strings 9 and illustrates that in such an embodiment it is possible and beneficial to use a wide, but thin ribbon 16 (which may extend outward from the sub-assembly 6) in order to avoid too many overly thick layers, such as the thicker, narrower layer 15, which can also be used. At the overlap of two strings 9, a thin insulation layer 17 (e.g. a plastic foil) can be added to avoid any electric short. This insulating foil 17 should have a low coefficient of friction in order to allow both strings 9 to slide on each other and thereby adjust for thermal expansion in this direction.

While FIG. 3b shows gaps between the solar cells along the string 9 as in the string 8 of FIG. 3a, the gaps in FIG. 3b can be significantly smaller than those of FIG. 3a or non-existent because, in contrast to the string 8 of FIG. 3a, the string 9 in FIG. 3b according to an embodiment of the invention does not need to loop a cable connection from the front to the back of adjacent solar cells. Rather, in FIG. 3b the gaps along the string 9 can be omitted because the electrical connections of the solar cells along the string can be made along the front and back at the top and bottom of the shingled solar cells and do not need to loop from the front to the back of adjacent solar cells. Moreover, as illustrated in FIG. 8b, gaps between parallel strings 9 can also be avoided completely by using the insulation layer 17 or another element which allows sliding of the parallel strings relative to each other for prevention of thermal stresses. The combination of these features allows all or nearly all of the surface area of a panel so formed to be effectively used.

Moreover, an embodiment of the present invention advantageously avoids having to use long lengths of shingled solar cells by providing the sub-assemblies 6 in strings 9, 10, such as that shown in FIGS. 3b and 3c, and/or the arrangement of the strings 9 shown in FIGS. 8a-b. Long lengths of shingled solar cells (see stress relieving elements required in US 20140124014A1) will be subject to increased thermal stress and will cause breakage.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

1 Square crystalline silicon wafer
2 Busbar
3 Grid finger
4 Cut of a solar cell (in this case ⅙)
5 Flat metal wire (“ribbon”)
6 Sub-assembly
7 Overlap
8 String out of conventional solar cells (in this case four pieces)
9 String out of four parallel oriented sub-assemblies
10 String out of four sub-assemblies with neighbors are rotated 180° to each other
11 Direction of current
12 Stress relief (e.g. flexible metal wire)
13 Electric bypass device (e.g. diode)
14 Electrical connection from “5” to “13”
15 Thick narrow ribbon
16 Thin wide ribbon
17 Insulation layer

What is claimed is:

1. A solar panel, comprising: a plurality of solar cells electrically connected to one another in a string along a string direction, each of the solar cells being made up of solar cell strips that are shingled with respect to one another along a shingling direction, wherein the shingling direction is perpendicular to the string direction.

2. The solar panel according to claim 1, wherein adjacent ones of the solar cells along the string are rotated 180 degrees with respect to one another.

3. The solar panel according to claim 2, wherein polarities of the adjacent solar cells are flipped with respect to each other so as to provide a meandering current direction along the string.

4. The solar panel according to claim 1, wherein the string is disposed adjacent to and overlapping with parallel strings such that no gaps exist between the strings in the shingling direction.

5. The solar panel according to claim 4, wherein an insulation layer is disposed between the parallel strings in an area of overlap.

6. The solar panel according to claim 1, wherein there is no gap between the solar cells along the string direction.

7. The solar panel according to claim 1, wherein adjacent ones of the solar cells are oriented parallel to each other and connected to each other in the string by two straight wires, one of the straight wires extending along front sides at a first outer edge of the solar cells and the other one of the straight wires extending along back sides at a second outer edge of the solar cells, the first outer edge being opposite to the second outer edge in the shingling direction.

8. The solar panel according to claim 1, further comprising a plurality of the strings disposed adjacent to each other in the shingling direction.

9. A method of manufacturing a solar panel comprising:
forming solar cells that are made up of solar cell strips that are shingled with respect to one another along a shingling direction;
electrically connecting the solar cells to each other in a string along a string direction, the shingling direction being perpendicular to the string direction.

10. The method according to the claim 9, wherein the solar cells are formed by cutting a solar cell into strips and then shingling the strips with respect to each other along long edges of the strips.

11. The method according to claim 9, wherein adjacent ones of the solar cells along the string are rotated 180 degrees with respect to one another.

12. The method according to claim 11, wherein polarities of the adjacent solar cells are flipped with respect to each other so as to provide a meandering current direction along the string.

13. The method according to claim 9, further comprising arranging the string adjacent to and overlapping with parallel strings such that no gaps exist between the strings in the shingling direction.

14. The method according to claim 13, further comprising arranging an insulation layer between the parallel strings in an area of overlap.

15. The method according to claim 9, wherein the solar cells are connected to each other in the string such that no gap exists between the solar cells along the string direction.

16. The method according to claim 9, wherein adjacent ones of the solar cells are oriented parallel to each other and connected to each other in the string by two straight wires, one of the straight wires extending along front sides at a first outer edge of the solar cells and the other one of the straight wires extending along back sides at a second outer edge of the solar cells, the first outer edge being opposite to the second outer edge in the shingling direction.

17. The method according to claim 9, further comprising arranging a plurality of the strings adjacent to each other in the shingling direction.
